(19) United States
(12) Patent Application Publication
(10) Pub. No.: US 2018/0136276 A1
(43) Pub. Date: May 17, 2018

(54) TEMPERATURE-MEASURING APPARATUS, INSPECTION APPARATUS, AND CONTROL METHOD

(71) Applicant: SEIKO EPSON CORPORATION, Tokyo (JP)

(72) Inventors: Sakiko SHIMIZU, Matsumoto-shi (JP); Akira IKEDA, Chino-shi (JP)

(73) Assignee: SEIKO EPSON CORPORATION, Tokyo (JP)

(21) Appl. No.: 15/799,483

(22) Filed: Oct. 31, 2017

(30) Foreign Application Priority Data
Nov. 14, 2016 (JP) 2016-221168

(51) Int. Cl. G01R 31/28

(52) U.S. Cl. CPC G01R 31/2875

(57) ABSTRACT

A temperature-measuring apparatus includes a first heat source capable of changing a heat generation temperature, a mounting portion on which a measurement subject accommodating a measurement target is mounted, a second heat source which is a heat source that heats the mounting portion and is capable of changing a heat generation temperature, a temperature sensor that detects a temperature of a predetermined position other than the measurement target on a heat flow path which comes from the first heat source and passes through the measurement subject, and a temperature computation portion that computes a temperature of the measurement target on the basis of heat balance characteristics of the temperature of the measurement target, a temperatures of the first heat source, a temperature of the second heat source, and the temperature of the predetermined position, the temperatures of the first heat source, the temperature of the second heat source, and the detected temperature of the predetermined position.

### BACKGROUND

### 1. Technical Field

The present invention relates to a temperature-measuring apparatus and the like which measure the internal temperatures of measurement subjects.

### 2. Related Art

In processes for manufacturing electronic components such as integrated circuits (IC), in order to decrease initial failure in advance and exhibit the reliability of the electronic components, inspection is carried out regarding the performance or functions of the manufactured electronic components (burn-in tests). As the burn-in tests, there are inspections that are carried out at high temperatures. For example, JP-A-2014-76519 discloses an electronic component inspection apparatus in which electronic components are transported to a socket that inputs/outputs electrical signals for inspection and are pressed onto the socket while being heated so as to connect terminals of the electronic components to the socket, thereby inspecting the electrical characteristics of the electronic components.

However, the above-described inspections that are carried out at high temperatures are carried out in a state in which electronic components are heated to temperatures necessary for inspection (for example, 150° C. or the like). Since it is not possible to install or insert temperature-measuring devices into electronic components, methods in which the internal temperatures of electronic components are presumptively measured from the operation status of elements having temperature characteristics such as diodes or transistors mounted in the electronic components and heat sources are controlled to heat the electronic components so that the internal temperatures of the electronic components reach the above-described necessary temperatures (hereinafter, referred to as “target temperatures”) are known. However, the above-described methods of the related art are not applicable in a case in which the electronic components are considered as black boxes as a whole and, furthermore, there have been problems in that the presumption of the internal temperatures of the entire electronic components from the operation status of elements has a margin of error, individual differences among electronic components, the fluctuation of ambient heat environments, and the like cause unevenness in terms of the actual internal temperature, and there are cases in which electronic components cannot be heated to the target temperatures. In addition, although it is necessary to cause the internal temperatures of electronic components to reach the target temperature during inspection, it cannot be said that the methods of the related art are highly accurate at all times as methods for measuring the internal temperatures of electronic components.

Hitherto, description has been made about electronic components, but the same problems can be caused for any components other than electronic components as long as it is necessary to heat the internal temperatures to the target temperatures for inspection and the like.

### SUMMARY

An advantage of some aspects of the invention is to provide a technique with which the internal temperatures of measurement subjects can be accurately measured and the transition of the internal temperatures can be monitored.

A first aspect of the invention is directed to a temperature-measuring apparatus including a first heat source capable of changing a heat generation temperature, amounting portion on which a measurement subject accommodating a measurement target is mounted, a second heat source which is a heat source that heats the mounting portion and is capable of changing a heat generation temperature, a temperature sensor that detects a temperature of a predetermined position other than the measurement target on a heat flow path which comes from the first heat source and passes through the measurement subject, and a temperature computation portion that computes a temperature of the measurement target on the basis of heat balance characteristics of the temperature of the measurement target, a temperature of the first heat source, a temperature of the second heat source, and the temperature of the predetermined position, the temperatures of the first heat source, the temperature of the second heat source, and the detected temperature of the predetermined position.

As another aspect of the invention, the invention may be configured as a control method of a temperature-measuring apparatus including a first heat source capable of changing a heat generation temperature, amounting portion on which a measurement subject accommodating a measurement target is mounted, a second heat source which is a heat source that heats the mounting portion and is capable of changing a heat generation temperature, and a temperature sensor that detects a temperature of a predetermined position other than the measurement target on a heat flow path which comes from the first heat source and passes through the measurement subject, the control method including: computing a temperature of the measurement target on the basis of heat balance characteristics of the temperature of the measurement target, a temperature of the first heat source, a temperature of the second heat source, and the temperature of the predetermined position, the temperature of the first heat source, the temperature of the second heat source, and the detected temperature of the predetermined position.

According to the first aspect of the invention and the like, it is possible to compute the temperature of the measurement target accommodated in the measurement subject from the temperatures of the first heat source, the temperature of the second heat source, and the detected temperature of the predetermined position using the heat balance characteristics of the temperature of the measurement target, the temperatures of the first heat source, the temperature of the second heat source, and the temperature of the predetermined position. According to the aspect, it becomes possible to accurately measure the internal temperatures of measurement subjects and monitor the transition of the internal temperatures.

As a second aspect of the invention, the temperature-measuring apparatus of the first aspect of the invention may be configured such that the heat generation temperature of the second heat source is set to be higher than the heat generation temperature of the first heat source.

According to the second aspect of the invention, it is possible to set the heat generation temperature of the second heat source to be higher than the heat generation temperature of the first heat source.

As a third aspect of the invention, the temperature-measuring apparatus of the first or second aspect of the invention may be configured such that the temperature sensor detects a temperature of the mounting portion as the temperature of the predetermined position.

According to the third aspect of the invention, it is possible to compute the temperature of the measurement target by detecting and using the temperature of the mounting portion on which the measurement subject is mounted.

As a fourth aspect of the invention, the temperature-measuring apparatus of any one of the first to third aspects of the invention may be configured such that the temperature-measuring apparatus further includes: a conveyance portion that holds and conveys the measurement subject to the mounting portion and halts at a predetermined halt position during measurement, and the first heat source is provided in the conveyance portion.

According to the fourth aspect of the invention, it is possible to heat the measurement subject (measurement target) using the conveyance portion that holds and conveys the measurement subject to the mounting portion and halts at the predetermined position between measurements. In addition, between measurements, it is possible to compute the temperature of the measurement target accommodated in the heated measurement subject. In addition, at this time, it is possible to block a surrounding of the measurement subject from heat by heating the mounting portion and stably heat the measurement subject.

As a fifth aspect of the invention, the temperature-measuring apparatus of any one of the first to fourth aspects of the invention may be configured to further include: a control portion that controls the temperatures of the heat sources on the basis of the computed temperature of the measurement target.

According to the fifth aspect of the invention, it is possible to realize the temperature control of the heat sources with which the temperature of the measurement target is set to a predetermined temperature.

As a sixth aspect of the invention, the temperature-measuring apparatus of any one of the first to fifth aspects of the invention may be configured such that the temperature computation portion variably sets the heat balance characteristics depending on heat environments.

According to the sixth aspect of the invention, it is possible to compute the temperature of the measurement target using the heat balance characteristics varied depending on heat environments.

As a seventh aspect of the invention, the temperature-measuring apparatus of the sixth aspect of the invention may be configured such that the temperature computation portion variably sets the heat balance characteristics depending on the heat environments on the basis of any one of a temperature in an apparatus chassis and a convection degree.

According to the seventh aspect of the invention, it is possible to compute the temperature of the measurement target using the heat balance characteristics varied depending on the temperature in the apparatus chassis and the convection degree in the apparatus chassis.

As an eighth aspect of the invention, an inspection apparatus including the temperature-measuring apparatus of any one of the first to seventh aspects of the invention, in which the measurement target is an electronic circuit, may be configured.

According to the eighth aspect of the invention, in the inspection apparatus of the electronic circuit, it is possible to accurately measure the temperature of the electronic circuit which is an inspection target as the measurement target and monitor the transition of the temperature.

As a ninth aspect of the invention, the inspection apparatus of the eighth aspect of the invention may be configured such that the mounting portion has a socket for the electronic circuit, a circuit inspection treatment device which is installed in a predetermined space in the apparatus chassis, has an operation compensation temperature that is lower than the temperatures of the heat sources, and is connected to the socket with an electrical wire and a cooling device for cooling the circuit inspection treatment device are provided, and the temperature computation portion variably sets the heat balance characteristics depending on a heat environment in the predetermined space.

According to the ninth aspect of the invention, the circuit inspection treatment device having an operation compensation temperature that is lower than the temperatures of the heat sources is installed in the predetermined space of the chassis, and this circuit inspection treatment device is cooled using the cooling device. Therefore, although the heat environment in the predetermined space in which the circuit inspection treatment device is installed may have an influence on a temperature of the electronic circuit, the heat balance characteristics varied depending on the heat environment in the predetermined space are used, and thus it is possible to realize computation in consideration of the influence in the computation of the temperature of the electronic circuit.

As a tenth aspect of the invention, the inspection apparatus of the eighth or ninth aspect of the invention may be configured such that the temperature sensor detects a temperature of a position close to the electrical wire in the socket as the temperature of the predetermined position.

According to the tenth aspect of the invention, it is possible to compute the temperature of the electronic circuit by detecting and using temperatures at positions in which heat flows from the heat sources easily flow.

### BRIEF DESCRIPTION OF THE DRAWINGS

The invention will be described with reference to the accompanying drawings, wherein like numbers reference like elements.

FIG. 1 is a schematic perspective view showing an overall constitution example of an IC test handler.

FIG. 2 is a pattern diagram showing a schematic constitution example of an inspection unit.

FIG. 3 is a schematic perspective view showing a constitution example of a second heating portion.

FIG. 4 is a view showing a heat flow path model of a first heat flow path.

FIG. 5 is a view showing a heat flow path model of a second heat flow path.

FIG. 6 is a view showing a data constitution example of a heat balance characteristic table.

FIG. 7 is a view describing a computation accuracy of an IC temperature T_{IC}.

FIG. 8 is a view showing a temperature distribution in an inspection unit.

FIG. 9 is a block diagram showing a principal function constitution example of a control device.

FIG. 10 is a flowchart showing a flow of treatments carried out by the control device.

FIG. 11 is a view showing a heat flow path model of a first heat flow path in a modification example.

FIG. 12 is a view showing a heat flow path model of a second heat flow path in the modification example.

FIG. 13 is a view showing a data constitution example of a heat balance characteristic table in the modification example.

FIG. 14 is a pattern diagram showing a schematic constitution example of an inspection unit in the modification example.

### DESCRIPTION OF EXEMPLARY EMBODIMENTS

Hereinafter, a preferred embodiment of the invention will be described with reference to the accompanying drawings. In the following description, an integrated circuit (IC) which is an electronic circuit will be used as a measurement subject, and an IC test handler used to inspect the electrical characteristics of IC at high temperatures will be exemplified. IC test handlers are installed and used in outsourced semiconductor assembly and tests (OSAT) or the like which undertake post-processes (assembly or inspection/tests) of semiconductor-manufacturing processes. The invention is not limited by the embodiment described below, and applicable formats of the invention are also not limited to the following embodiment. In addition, in the drawing, the same portion will be given the same reference symbol.

### Overall Constitution

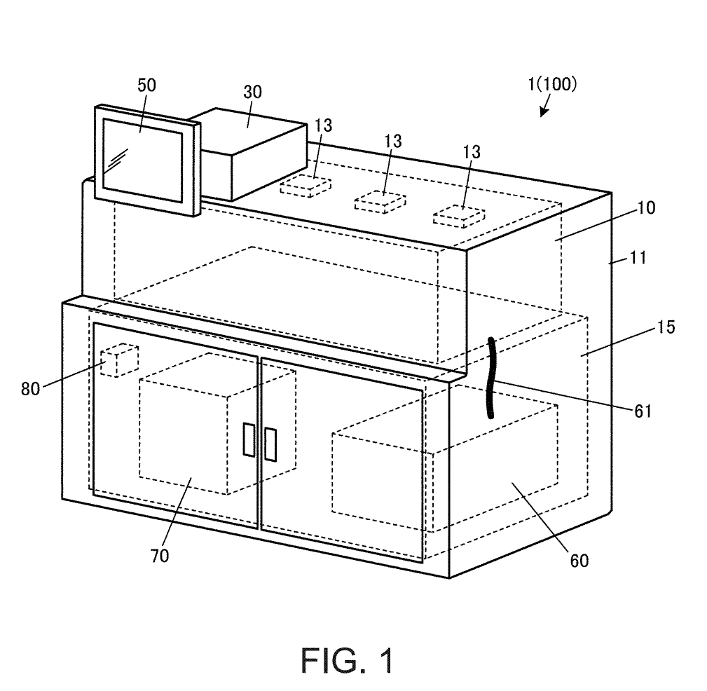

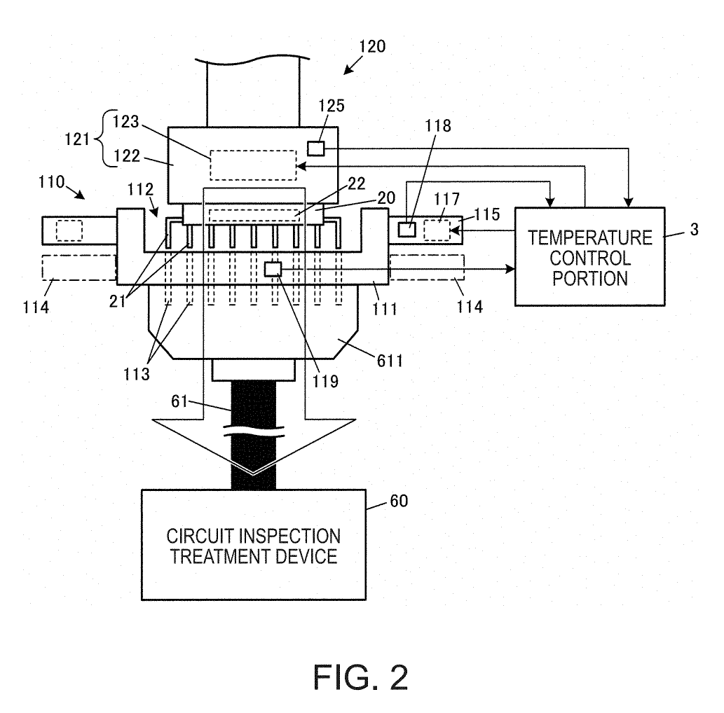

FIG. 1 is a schematic perspective view showing an overall constitution example of an IC test handler 1 which is an inspection apparatus 100, and FIG. 2 is a pattern diagram showing a schematic constitution example of an inspection unit 10 embedded into the IC test handler 1. The IC test handler 1 includes an inspection unit 10 constituting the upper portion of a substantially cuboid-shape chassis 11, a control device 30 controlling the operation of the inspection unit 10, a display device 50 for displaying the state of the inspection unit 10 and the like, and a plurality of neutralization devices (ionizer) 13 for removing static electricity in the inspection unit 10. In addition, the IC test handler 1 has an accommodation space 15 provided in the lower portion of the chassis 11 as a predetermined space in the apparatus chassis and includes a circuit inspection treatment device 60, a cooling device 70, and a thermometer 80 which are provided in the accommodation space 15.

The inspection unit 10 includes, as principal constitutions, a mounting portion 110 which is installed at an appropriate place in the inspection unit 10 and mounts an IC package 20 accommodating an IC 22 which is an inspection target (also a measurement target of internal temperatures described below) and an adsorption hand 120 as a conveyance portion which moves in the inspection unit 10 and sequentially conveys IC packages 20 toward the mounting portion 110. FIG. 2 shows a state in which the adsorption hand 120 conveys the IC package 20 up to the mounting portion 110.

The adsorption hand 120 adsorbs and holds the IC package 20 on a front end surface side using a suction mechanism, not shown, and conveys the IC package 20. This adsorption hand 120 has a first heating portion 121 which is a first heat source in a front end portion and is capable of heating and holding the IC package 20 (IC 22) at the same time. The first heating portion 121 is constituted by burying a heat generator (hereinafter, referred to as “hand heater”) 123 in a heat conductor 122.

The hand heater 123 is constituted so as to be capable of changing a heat generation temperature in a predetermined temperature range, and the heat generation temperature is controlled using a temperature control portion 373 constituting the control device 30. This hand heater 123 is intended to heat the IC 22 to a predetermined target temperature (for example, 150° C. or the like), and the temperature range in which the heat generation temperature can be changed is set to be, for example, room temperature to approximately 180° C.

The mounting portion 110 detachably holds the IC package 20 and has a socket 111 that conducts electrical signals between the circuit inspection treatment device 60 and the IC 22. The socket 111 has a recess portion 112 formed on an upper surface, and the IC package 20 is mounted in the socket 111 using the adsorption hand 120 at the time of inspection. In addition, the socket 111 includes a plurality of socket pins (electrical wires) 113 in an array which have one end portion exposed in the recess portion 112 and are electrically connected to individual terminals 21 of the IC 22 mounted in the recess portion 112. The other end portion of each of the socket pins 113 is connected to the end of an electrical wire of a corresponding cable 61 through a cable connector 611 and is connected to the circuit inspection treatment device 60.

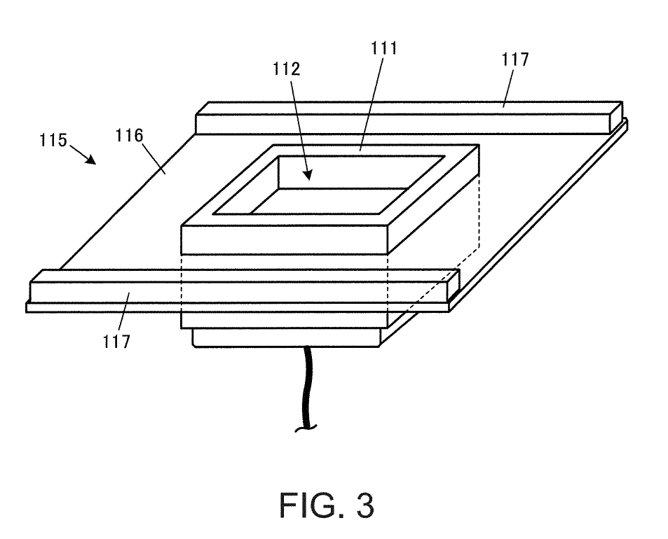

The mounting portion 110 has a second heating portion 115 which is a second heat source. FIG. 3 is a schematic perspective view showing a constitution example of the second heating portion 115. The second heating portion 115 is constituted by, for example, arranging rod-shaped heat generators 117 at outer circumferential portions of a stainless steel sheet 116. In the example of FIG. 3, the heat generators (hereinafter, these heat generators will also be collectively referred to as “socket heater”) 117 are arranged along two facing sides out of four sides of the stainless steel sheet 116. In addition, a through hole is provided in the center of the stainless steel sheet 116, and the recess portion 112 of the socket 111 is fitted and fixed thereto. Therefore, the second heating portion 115 is constituted so as to heat a region away from the IC package 20 at the outside of side surfaces of the IC package 20 (not shown in FIG. 3) mounted in the recess portion 112. The arrangement positions or the number of the heat generators 117 are not particularly limited, and the second heating portion 115 may be constituted by arranging the heat generators 117 at all of the four sides of the stainless steel sheet 116 so as to surround the IC package 20.

The socket heater 117 is constituted so as to be capable of changing a heat generation temperature in a predetermined temperature range like the hand heater 123, and the heat generation temperature is controlled to a higher temperature than the heat generation temperature of the hand heater 123 using the temperature control portion 373. In the present embodiment, the heat generation temperature of the socket heater 117 is set to a temperature that is higher than the heat generation temperature of the hand heater 123 by a predetermined value. The degree of the temperature difference may be appropriately set, and the predetermined value is preferably set to, for example, 20° C. or more. When the heat generation temperature by the socket heater 117 is set to be 20° C. or more higher than the heat generation temperature of the hand heater 123, a heat-blocking effect described below improves, and it is possible to stably heat the IC 22. The temperature range in which the heat generation temperature can be changed is set to be, for example, room temperature to approximately 180° C.

The operation of the inspection unit 10 regarding the inspection of one IC 22 will be briefly described. First, the adsorption hand 120 adsorbs and holds the IC package 20 accommodating the IC 22 which is an inspection target, conveys the IC package up to the mounting portion 110, and mounts the IC package in the recess portion 112 of the socket 111. At this time, the adsorption hand 120 moves downward from the position in FIG. 2 and presses the IC package 20 into the recess portion 112, whereby the respective terminals 21 of the IC 22 are brought into contact with the corresponding socket pins 113 so as to mount the IC package 20 in the socket 111, and the adsorption hand remains halted for a predetermined time at the moved-down position as a halt position. During this halt, inspection is carried out, and, at the time of inspection, in the first heating portion 121, the hand heater 123 generates heat at a predetermined heat generation temperature and heats the IC package 20 through the heat conductor 122 in contact with the IC package 20. The heating may be initiated even before the mounting of the IC package 20 into the socket 111. Therefore, a state in which the inside of the IC 22 is heated to the target temperature is formed. In addition, the socket heater 117 generates heat at a heat generation temperature that is higher than the heat generation temperature of the hand heater 123 at the same time as the above-described heating and heats the outside of the side surfaces of the IC package 20. In addition, the circuit inspection treatment device 60 carries out an inspection treatment while the adsorption hand 120 remains halted and inspects the electrical characteristics of the IC 22 which is the inspection target. When the inspection ends, the adsorption hand 120 conveys the IC package 20 from the mounting portion 110, and the process proceeds for inspection regarding the subsequent IC 22.

In the inspection unit 10 operating as described above, the adsorption hand 120 includes a first temperature detector 125 for detecting the temperature of the first heating portion 121. The first temperature detector 125 may be installed at an arbitrary position in the first heating portion 121 such as the inside, surface, or the like of the first heating portion 121.

The mounting portion 110 includes a second temperature detector 118 for detecting the temperature of the second heating portion 115. The second temperature detector 118 is installed at a position close to the socket heater 117.

The mounting portion 110 includes a third temperature detector 119 which is a temperature sensor that detects the temperature of a predetermined position other than the IC 22. The third temperature detector 119 may be installed at an arbitrary position in the socket 111, but is preferably installed at a position which is lower than the IC package 20 (on the downstream side of a heat flow direction) and is close to any one of the socket pins 113. As described below, a heat flow from the hand heater 123 moves in a heat flow direction shown by an arrow in FIG. 2, and heat is discharged toward the accommodation space 15 on the lower side through the socket 111. In addition, the temperature control portion 373 computes (assumes) a temperature (hereinafter, referred to as “IC temperature”) T_{IC} of the IC 22 accommodated in the IC package 20 using a heat flow path model in which heat flows from the hand heater 123 toward the accommodation space 15. Since the main body of the socket 111 is formed of a material having a low heat conductivity such as a polyetheretherketone (PEEK) resin, heat flows transmitting through the socket 111 mainly gather in the socket pins 113 which are conductors having a high heat conductivity. Therefore, the use of the temperature of the socket pins 113 rather than the temperature of the main body portion as a socket temperature T_{SKT} described below enables the accurate computation of the IC temperature T_{IC}.

The control device 30 controls the operation of the inspection unit 10 regarding the inspection of the IC 22. In this control device 30, the temperature control portion 373 computes and uses the IC temperature T_{IC} of the IC 22 which is the inspection target and controls the heat generation temperature of the hand heater 123 as needed so that the IC temperature T_{IC} reaches the target temperature.

The circuit inspection treatment device 60 is constituted of a computer or the like, input and output electrical signals to and from the IC 22 which is the inspection target, and carries out a treatment for inspecting the electrical characteristics of the IC 22 (inspection treatment). Specifically, the circuit inspection treatment device 60 outputs inspection electrical signals to the IC 22 through the socket. In addition, the circuit inspection treatment device analyzes electrical signals that are input from the IC 22 in response to the outputted electrical signals, thereby determining whether the electrical characteristics are favorable or poor and selecting favorable products/poor products.

The cooling device 70 is intended to cool the circuit inspection treatment device 60 and air-cools the accommodation space 15 by feeding indoor air into the accommodation space 15 using, for example, a fan and discharging the air in the accommodation space 15. Since the operation guaranteed temperature of the circuit inspection treatment device 60 is approximately room temperature, heat flowing from the hand heater 123 is discharged into the accommodation space 15 as described above. The cooling device 70 dissipates heat discharged into the accommodation space 15 as described above and prevents the temperature of the circuit inspection treatment device 60 from increasing. Due to this cooling device 70, the temperature of the accommodation space 15 is maintained at approximately room temperature (approximately 24° C. to 25° C.). The cooling device is not limited to air cooling-type cooling devices, and fanless-type cooling devices or water cooling-type cooling devices may also be used. In addition, air conditioners cooling the circuit inspection treatment device using heat media may also be used as the cooling device 70.

The thermometer 80 detects the temperature of the accommodation space 15 and outputs the temperature to the control device 30.

### Principle

### (1) Heating of IC

In the present embodiment, the temperature of the hand heater 123 is set to a high temperature such as 150° C. or the like, the circuit inspection treatment device 60 and the like are installed on the lower side of the inspection unit 10 in the accommodation space 15, and the temperature of the accommodation space 15 is lower than the heat generation temperature of the hand heater 123. As long as the cooling device 70 is being driven, the temperature of the accommodation space 15 is approximately room temperature. Therefore, heat flowing from the hand heater 123 moves downwards as shown by the arrow in FIG. 2 and is discharged into the accommodation space 15 (external air) through the socket 111 and the cable 61. In the present embodiment, the socket heater 117 heats the outside of the side surfaces of the IC package 20 at the heat generation temperature that is higher than the heat generation temperature of the hand heater 123.

Therefore, herein, two heat flow paths along which heat flows from a first heat source position P_{H1} and a second heat source position P_{H2} to an arbitrary position (hereinafter, referred to as “internal space position”) P_{OUT} in the accommodation space 15 will be considered. The first one is a heat flow path which starts from the first heat source position P_{H1} and the second heat source position P_{H2} respectively, joins together before an internal position (hereinafter, referred to as “position in the IC”) P_{IC} in the IC 22 which is the measurement target (also the inspection target), and reaches the internal space position P_{OUT} (a first heat flow path). The second one is a heat flow path which starts from the first heat source position P_{H1} and the second heat source position P_{H2} respectively, joins together before a predetermined position (hereinafter, referred to as “socket position”) P_{SKT} in the socket 111, and reaches the internal space position P_{OUT} (a second heat flow path). The first heat source position P_{H1} is, for example, the installation position of the first temperature detector 125, the second heat source position P_{H2} is the installation position of the second temperature detector 118, and the socket position P_{SKT} is the installation position of the third temperature detector 119.

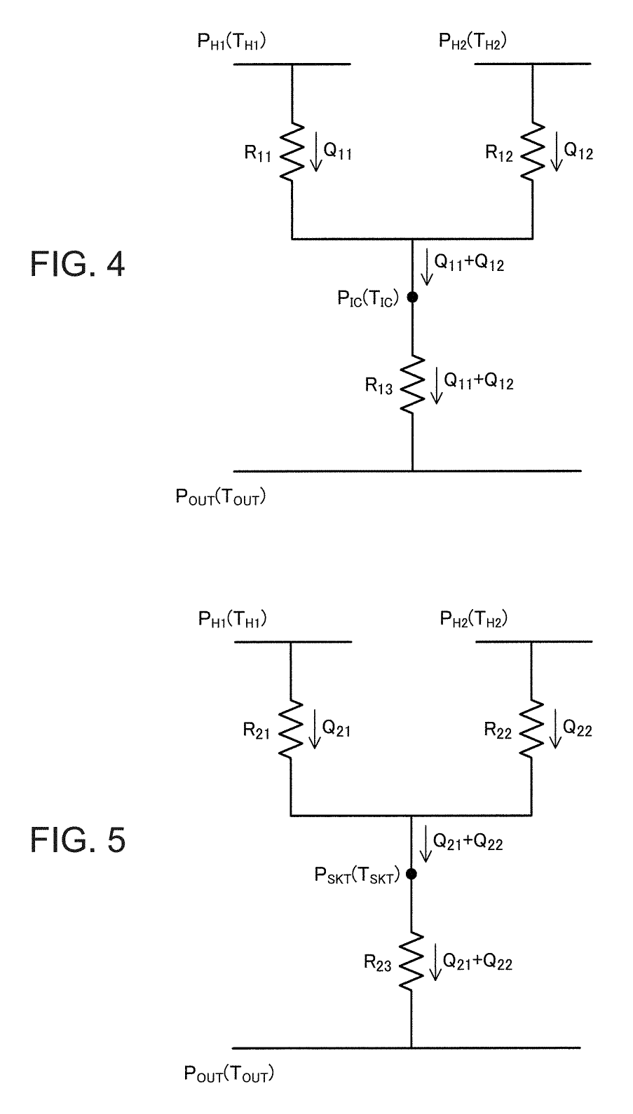

When a heat flow moves along the first heat flow path or the second heat flow path, the heat flow is affected by the inflow of heat from the outside and the outflow of heat to the outside during the movement process. In the present embodiment, this heat exchange will be referred to as “heat balance”. When an electrical circuit-like model of the first heat flow path is produced in consideration of this heat balance, it is possible to build a heat flow path model as in FIG. 4. As a path from the first heat source position P_{H1} to the position in the IC P_{IC} or a path from the second heat source position P_{H2} to the position in the IC P_{IC} and a path from the position in the IC P_{IC} to the internal space position P_{OUT}, a variety of paths can be considered. In the heat flow path model of FIG. 4, each of the paths is expressed as one heat resistance. The values of the respective heat resistances are unknown.

Similarly, when an electrical circuit-like model of the second heat flow path is produced in consideration of the heat balance, it is possible to build a heat flow path model as in FIG. 5. As a path from the first heat source position P_{H1} to the socket position P_{SKT} or a path from the second heat source position P_{H2} to the socket position P_{SKT} and a path from the socket position P_{SKT} to the internal space position P_{OUT}, a variety of paths can be considered. In the heat flow path model of FIG. 5, each of the paths is expressed as one heat resistance. The values of the respective heat resistances are unknown.

First, a heat flow Q₁₁ reaching the position in the IC P_{IC} from the first heat source position P_{H1} in the first heat flow path of FIG. 4 can be expressed by Expression (1) using a temperature (hereinafter, referred to as “first heat source temperature”) T_{H1} of the first heat source position P_{H1}, an IC temperature T_{IC} which is the temperature of the position in the IC P_{IC}, and a heat resistance R₁₁ between the first heat source position P_{H1} and the position in the IC P_{IC}. A heat flow Q₁₂ reaching the position in the IC P_{IC} from the second heat source position P_{H2} can be expressed by Expression (2) using a temperature (hereinafter, referred to as “second heat source temperature”) T_{H2} of the second heat source position P_{H2}, the IC temperature T_{IC}, and a heat resistance R₁₂ between the second heat source position P_{H2} and the position in the IC P_{IC}. In addition, a heat flow Q₁₁+Q₁₂ which joins together before the position in the IC P_{IC} and reaches the internal space position P_{OUT} can be expressed by Expression (3) using the IC temperature T_{IC}, a temperature (hereinafter, referred to as “internal space temperature”) T_{OUT} of the internal space position P_{OUT}, and a heat resistance R₁₃ between the position in the IC P_{IC} and the internal space position P_{OUT}.

$$\begin{matrix}{Q}_{11} = \frac{{T}_{H 1} - {T}_{IC}}{{R}_{11}} & ( 1 ) \\ {Q}_{12} = \frac{{T}_{H 2} - {T}_{IC}}{{R}_{12}} & ( 2 ) \\ {Q}_{11} + {Q}_{12} = \frac{{T}_{IC} - {T}_{OUT}}{{R}_{13}} & ( 3 )\end{matrix}$$

In addition, a heat flow Q₂₁ reaching the socket position P_{SKT} from the first heat source position P_{H1} in the second heat flow path of FIG. 5 can be expressed by Expression (4) using the first heat source temperature T_{H1}, a temperature (hereinafter, referred to as “socket temperature”) T_{SKT} of the socket position P_{SKT}, and a heat resistance R₂₁ between the first heat source position P_{H1} and the socket position P_{SKT}. A heat flow Q₂₂ reaching the socket position P_{SKT} from the second heat source position P_{H2} can be expressed by Expression (5) using the second heat source temperature T_{H2}, the socket temperature T_{SKT}, and a heat resistance R₂₂ between the second heat source position P_{H2} and the socket position P_{SKT}. In addition, a heat flow Q₂₁+Q₂₂ which joins together before the socket position P_{SKT} and reaches the internal space position P_{OUT} can be expressed by Expression (6) using the socket temperature T_{SKT}, the internal space temperature T_{OUT}, and a heat resistance R₂₃ between the socket position P_{SKT} and the internal space position P_{OUT}.

$$\begin{matrix}{Q}_{21} = \frac{{T}_{H 1} - {T}_{SKT}}{{R}_{21}} & ( 4 ) \\ {Q}_{22} = \frac{{T}_{H 2} - {T}_{SKT}}{{R}_{22}} & ( 5 ) \\ {Q}_{21} + {Q}_{22} = \frac{{T}_{SKT} - {T}_{OUT}}{{R}_{23}} & ( 6 )\end{matrix}$$

Expressions (1), (2), and (3) can be rearranged as Expression (7), and Expressions (4), (5), and (6) can be rearranged as Expression (8).

$$\begin{matrix}\frac{{T}_{H 1} - {T}_{IC}}{{R}_{11}} + \frac{{T}_{H 2} - {T}_{IC}}{{R}_{12}} = \frac{{T}_{IC} - {T}_{OUT}}{{R}_{13}} & ( 7 ) \\ \frac{{T}_{H 1} - {T}_{SKT}}{{R}_{21}} + \frac{{T}_{H 2} - {T}_{SKT}}{{R}_{22}} = \frac{{T}_{SKT} - {T}_{OUT}}{{R}_{23}} & ( 8 )\end{matrix}$$

Next, in order to compute the IC temperature T_{IC}, the element of the internal space temperature T_{OUT} is removed from Expression (7) and Expression (8). In order for that, Expression (7) is rearranged for the internal space temperature T_{OUT}, thereby obtaining Expression (9), and Expression (8) is rearranged for the internal space temperature T_{OUT}, thereby obtaining Expression (10).

$$\begin{matrix}{R}_{13} ( \frac{{T}_{H 1} - {T}_{IC}}{{R}_{11}} + \frac{{T}_{H 2} - {T}_{IC}}{{R}_{12}} - \frac{{T}_{IC}}{{R}_{13}} ) = - {T}_{OUT} & ( 9 ) \\ {R}_{23} ( \frac{{T}_{H 1} - {T}_{SKT}}{{R}_{21}} + \frac{{T}_{H 2} - {T}_{SKT}}{{R}_{22}} - \frac{{T}_{SKT}}{{R}_{23}} ) = - {T}_{OUT} & ( 10 )\end{matrix}$$

Expression (9) and Expression (10) can be rearranged as Expression (11).

$$\frac{{R}_{13}}{{R}_{11}} ( {T}_{H 1} - {T}_{IC} ) + \frac{{R}_{13}}{{R}_{12}} ( {T}_{ H 2} - {T}_{IC} ) - {T}_{IC} = \frac{{R}_{23}}{{R}_{21}} ( {T}_{H 1} - {T}_{SKT} ) + \frac{{R}_{23}}{{R}_{22}} ( {T}_{H 2} - {T}_{SKT} ) - {T}_{SKT} \qquad ( 11 )$$

Here, the coefficients of the respective elements of Expression (11) can be rearranged as Expressions (12), (13), (14), and (15).

$$\begin{matrix}\frac{{R}_{13}}{{R}_{11}} = a & ( 12 ) \\ \frac{{R}_{13}}{{R}_{12}} = b & ( 13 ) \\ \frac{{R}_{23}}{{R}_{21}} = c & ( 14 ) \\ \frac{{R}_{23}}{{R}_{22}} = d & ( 15 )\end{matrix}$$

At this time, Expression (11) can be rearranged as Expression (16).

a(T_{H1}−T_{IC})+b(T_{H2}−T_{IC})−T_{IC}=c(T_{H1}−T_{SKT})+d(T_{H2}−T_{SKT})−T_{SKT} (16)

When Expression (16) is rearranged for the IC temperature T_{IC}, Expression (17) is obtained.

$${T}_{IC} = \frac{a - c}{a + b + 1} {T}_{H 1} + \frac{b - d}{a + b + 1} {T}_{H 2} + \frac{c + d + 1}{a + b + 1} {T}_{SKT} \qquad ( 17 )$$

Here, the respective coefficients a to d defined by Expressions (12), (13), (14), and (15) are represented by the heat resistances R₁₁, R₁₂, R₁₃, R₂₁, R₂₂, and R₂₃ and are considered to represent the influences on heat flows moving through the first heat flow path and the second heat flow path of heat balance generated by the heat resistances. That is, the respective coefficients a to d can be said to be values indicating the heat balance characteristics of the IC temperature T_{IC}, the first heat source temperature T_{H1}, the second heat source temperature T_{H2}, and the socket temperature T_{SKT}. Heat balance relative coefficients D₁, D₂, and D₃ represented by Expressions (18), (19), and (20) are introduced using the respective coefficients a to d.

$$\begin{matrix}\frac{a - c}{a + b + 1} = {D}_{1} & ( 18 ) \\ \frac{b - d}{a + b + 1} = {D}_{2} & ( 19 ) \\ \frac{c + d + 1}{a + b + 1} = {D}_{3} & ( 20 )\end{matrix}$$

Expression (17) can be rearranged as Expression (21) using the heat balance relative coefficients D₁, D₂, and D₃.

T_{IC}=D₁T_{H1}+D₂T_{H2}+D₃T_{SKT} (21)

In Expression (21), the first heat source temperature T_{H1} can be detected using the first temperature detector 125, the second heat source temperature T_{H2} can be detected using the second temperature detector 118, and the socket temperature T_{SKT} can be detected using the third temperature detector 119, and thus all of the temperatures are known. Therefore, when the values of the heat balance relative coefficients D₁, D₂, and D₃ are specified in advance, it is possible to compute the IC temperature T_{IC}. In addition, these heat balance relative coefficients D₁, D₂, and D₃ can also be said to be values indicating the heat balance characteristics of the IC temperature T_{IC}, the first heat source temperature T_{H1}, the second heat source temperature T_{H2}, and the socket temperature T_{SKT}.

However, the heat resistance R₁₃ in the heat flow path from the position in the IC P_{IC} to the internal space position P_{OUT} or the heat resistance R₂₃ in the heat flow path from the socket position P_{SKT} to the internal space position P_{OUT} is affected by the heat environment in the accommodation space 15. In addition, this heat environment varies depending on a convection degree in the accommodation space 15. Therefore, in the present embodiment, the convection degree in the accommodation space 15 is defined by the combination of the driving state of the cooling device 70 and the driving state of the neutralization devices 13, and values of the heat balance relative coefficients D₁, D₂, and D₃ in heat environments corresponding to the respective convection degrees (that is, in the corresponding driving states of the cooling device 70 and the neutralization devices 13) are specified in advance.

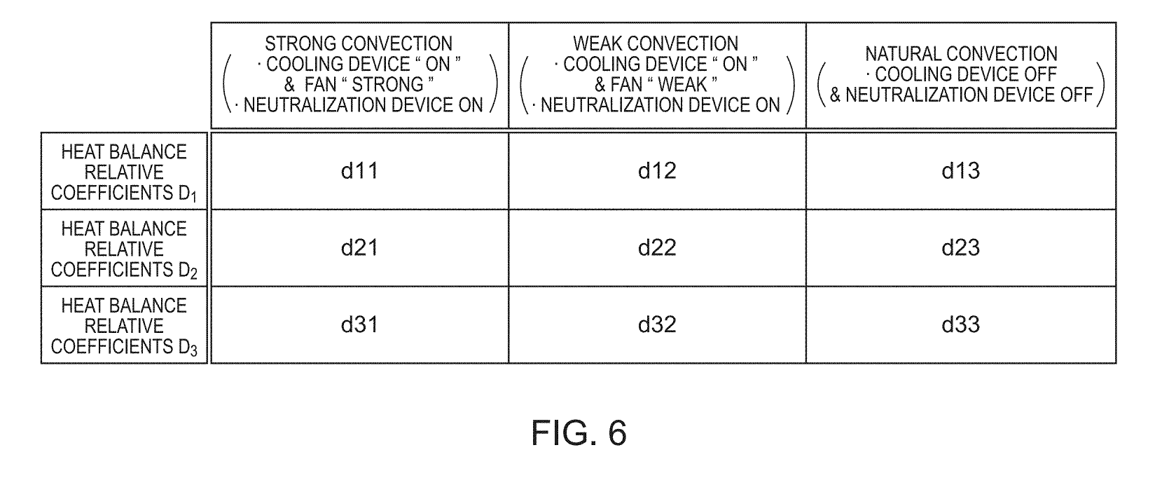

FIG. 6 is a view showing a data constitution example of a heat balance characteristic table in which the heat balance relative coefficients D₁, D₂, and D₃ are specified. As shown in FIG. 6, in the heat balance characteristic table, values of the heat balance relative coefficients D₁, D₂, and D₃ are separately stored depending on three different convection degrees of “strong convection”, “weak convection”, and “natural convection”. In the example of FIG. 6, it is assumed that the air volume of the fan constituting the cooling device 70 can be selected to be “strong” or “weak”, and “strong convection” refers to a case in which the cooling device 70 is being driven, the air volume of the fan is set to be “strong”, and the neutralization devices 13 are being driven. “Weak convection” refers to a case in which the cooling device 70 is being driven, the air volume of the fan is set to be “weak”, and the neutralization devices 13 are being driven. “Natural convection” refers to a case in which both the cooling device 70 and the neutralization devices 13 remain halted.

In addition, at the time of inspection, the first heat source temperature T_{H1}, the second heat source temperature T_{H2}, and the socket temperature T_{SKT} are detected as needed, and the IC temperature T_{IC} is computed according to Expression (21) by reading and using the values of the heat balance relative coefficients D₁, D₂, and D₃ corresponding to the actual convection degree (the driving state of the cooling device 70 and the neutralization devices 13) in the accommodation space 15. The computed IC temperature T_{IC} may be appropriately displayed on the display device 50 and presented to users.

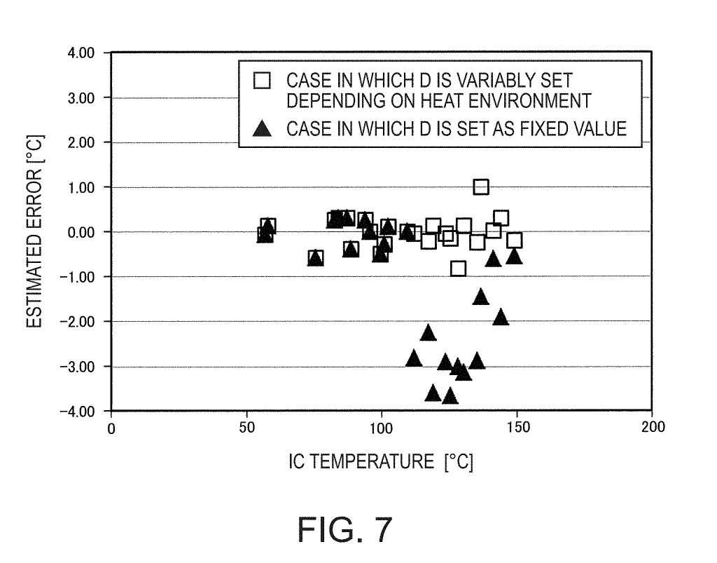

FIG. 7 is a view describing the computation accuracy of the IC temperature T_{IC} and shows estimated errors plotted for a case in which the IC temperature T_{IC} is computed using the heat balance relative coefficients D₁, D₂, and D₃ as fixed values and a case in which the IC temperature T_{IC} is computed by reading and using the values of the heat balance relative coefficients D₁, D₂, and D₃ corresponding to the convection degree from the heat balance characteristic table while changing the driving states of the cooling device 70 and the neutralization devices 13. The estimated errors were obtained by measuring the actual value of the IC temperature T_{IC} in conjunction. As shown in FIG. 7, the IC temperature T_{IC} can be more highly accurately measured by, for example, considering the convection degree in the accommodation space 15 as the heat environment and variably setting the heat balance relative coefficients D₁, D₂, and D₃.

(2) Blocking Surrounding of IC from Heat

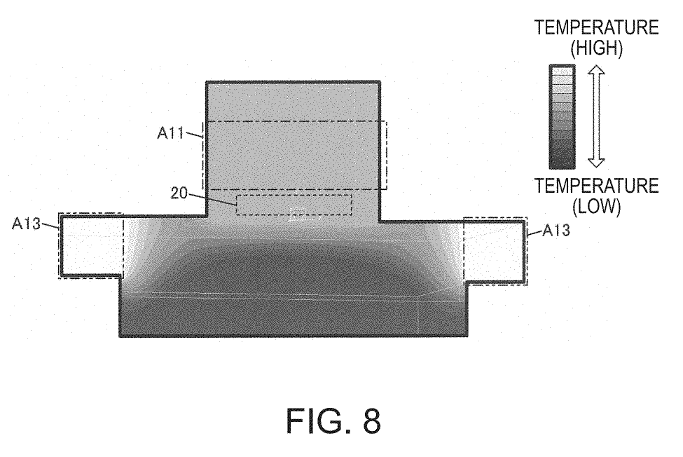

The socket heater 117 heats the outside of the side surfaces of the IC package 20, thereby blocking a surrounding of the IC package 20 from heat. FIG. 8 is a view showing a temperature distribution at the constituent portions shown in FIG. 2 in the inspection unit 10. First, when attention is paid to the hand heater 123, a peripheral region (the portion of the first heating portion 121) All of the hand heater 123 which is surrounded by the dot-and-dash line has a temperature that is higher than the temperature below the IC package 20 (the accommodation space 15 side on the lower side of the inspection unit 10). Since the hand heater 123 is buried in the heat conductor 122 and is not in contact with external air, the heat flux toward the external air of the region A11 is small. Therefore, heat flows from the hand heater 123 move toward the lower portion in FIG. 8, and heat is discharged in the accommodation space 15 on the lower side of the inspection unit 10.

A peripheral region (the portion of the second heating portion 115) A13 of the socket heater 117 which is surrounded by the dashed-two dotted line also has a temperature that is higher than the temperature below the IC package 20 (the accommodation space 15 side on the lower side of the inspection unit 10) and the temperature in the peripheral region A11. Since the heat generation temperature of the socket heater 117 is adjusted to be higher than the heat generation temperature of the hand heater 123, the temperature of the region A13 becomes highest in the entire regions. Meanwhile, in this region A13, the heat flux is also large. This is because the socket heater 117 is exposed in the inspection unit 10 or disposed in a highly heat-conductive member and a large temperature difference (temperature gradient) is caused between both portions of the surface as a boundary. In addition, since the temperature of the socket 111 is higher than the temperature of the IC 22, heat flows from the socket heater 117 do not reach the IC 22 and act to heat portions outside the side surfaces of the IC 22 or a portion below the IC. What has been described above is also evident from the fact that, in FIG. 8, no temperature changes are observed in the IC 22 and the surrounding thereof (portions outside the sides of the IC or a portion below the IC). When the IC package 20 is heated using the socket heater 117 from the outside of the side surfaces as described above, the surrounding of the IC package 20 is blocked from heat.

In the downstream portion in a heat flow direction from the hand heater 123, the accommodation space 15 is formed, and there is a temperature difference between the upstream portion and the downstream portion. Furthermore, the accommodation space 15 is cooled using the cooling device 70, and thus a phenomenon in which heat for heating the IC 22 flows toward the accommodation space 15 side may occur. However, according to the present embodiment, it is possible to block the surrounding of the IC package 20 accommodating the IC 22 from heat as described above, and thus the IC 22 can be stably heated to the target temperature.

### Function Constitution

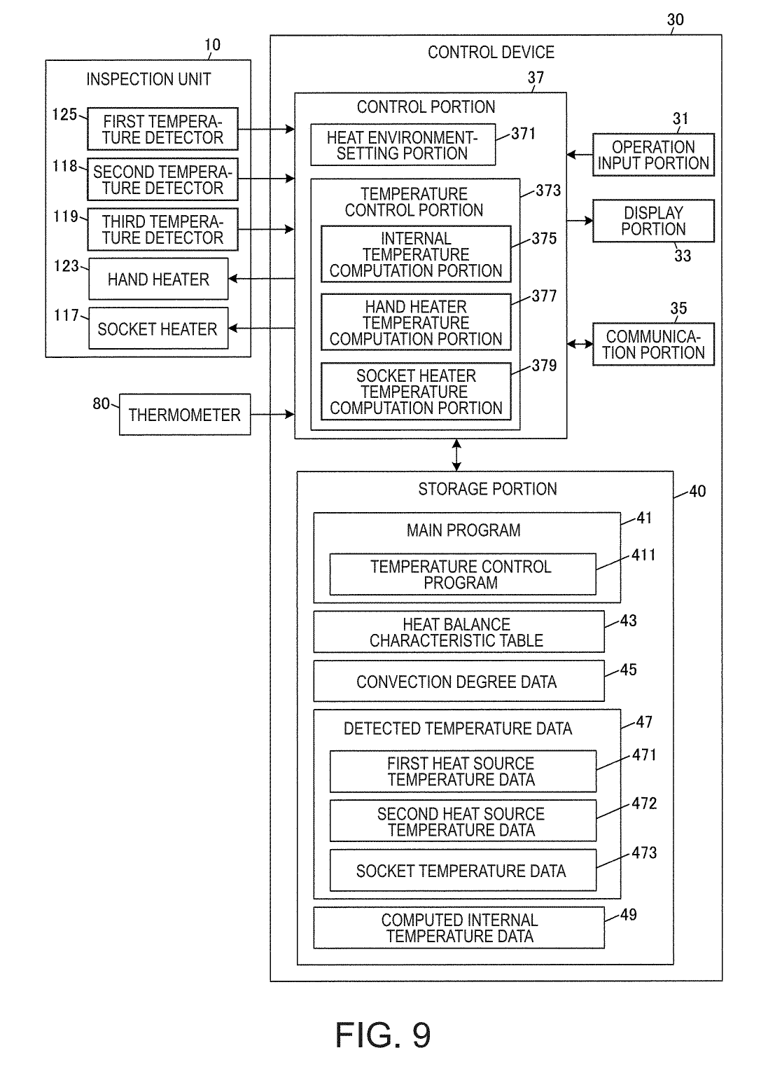

FIG. 9 is a block diagram showing a principal function constitution example of the control device 30. As shown in FIG. 9, the control device 30 includes an operation input portion 31, a display portion 33, a communication portion 35, a control portion 37, and a storage portion 40 and constitutes the temperature-measuring apparatus together with the inspection unit 10 or the thermometer 80.

The operation input portion 31 receives a variety of operation inputs from users and outputs operation input signals corresponding to the operation inputs to the control portion 37. The operation input portion can be realized using a button switch, a lever switch, a dial switch, a touch panel, or the like.

The display portion 33 is realized using a display device such as a liquid crystal display (LCD), an organic electroluminescence display (OELD), an electronic paper display, or the like and displays a variety of information on the basis of display signals from the control portion 37. In FIG. 1, the display device 50 corresponds to this display portion.

The communication portion 35 is a communication device for sending and receiving data to and from the outside on the basis of the control by the control portion 37. For example, the control device 30 is capable of sending or receiving necessary data to and from the circuit inspection treatment device 60 through the communication portion 35. As the communication method of the communication portion 35, a variety of methods such as a method of wireless connection using wireless communication, a method of wire connection using cables based on predetermined communication standards, and a method of connection through an intermediate device, which is called a cradle or the like and also functions as a charger, are applicable.

The control portion 37 controls the input and output of data to and from a variety of functional portions, executes a variety of arithmetic processing on the basis of predetermined programs or data, operation input signals from the operation input portion 31, detected temperatures input from the first temperature detector 125 as needed, detected temperatures input from the second temperature detector 118 as needed, detected temperatures input from the third temperature detector 119 as needed, the temperature of the accommodation space 15 input from the thermometer 80 as needed, and the like, and controls the operation of the inspection unit 10 regarding the inspection of the IC 22. The control portion can be realized using, for example, a microprocessor such as a central processing unit (CPU) or a graphics processing unit (GPU) or an electronic component such as an application specific integrated circuit (ASIC), a field programmable gate array (FPGA), or an IC memory.

The control portion 37 includes a heat environment-setting portion 371 and a temperature control portion 373.

The heat environment-setting portion 371 sets the convection degree in the actual accommodation space 15. For example, the heat environment-setting portion generates convection degree data which set the driving state of the cooling device 70 and the driving state of the neutralization devices 13. The driving state of the cooling device 70 includes the setting of whether or not the cooling device being driven (driven/halted) and the air volume setting of the fan (“strong” or “weak”). For the neutralization devices 13, the heat environment-setting portion sets whether or not the neutralization devices are driven (driven/halted). In addition, the heat environment-setting portion 371 renews convection degree data 45 each time the driving states of the cooling device 70 and the neutralization devices 13 are changed.

The temperature control portion 373 controls the heat generation temperature of the hand heater 123 so that the IC temperature T_{IC} reaches the target temperature and controls the heat generation temperature of the socket heater 117 on the basis of the heat generation temperature of the hand heater 123. The temperature control portion 373 includes an internal temperature computation portion 375, a hand heater temperature computation portion 377, and a socket heater temperature computation portion 379.

The internal temperature computation portion 375 computes the IC temperature T_{IC} according to Expression (21) using the heat balance relative coefficients D₁, D₂, and D₃, the first heat source temperature T_{H1}, the second heat source temperature T_{H2}, and the socket temperature T_{SKT}. At this time, regarding the heat balance relative coefficients D₁, D₂, and D₃, the values of the corresponding heat balance relative coefficients D₁, D₂, and D₃ are read from the heat balance characteristic table 43 and used according to the convection degree data 45.

The hand heater temperature computation portion 377 computes the heat generation temperature of the hand heater 123 on the basis of the difference between the IC temperature T_{IC} computed by the internal temperature computation portion 375 and the target temperature.

The socket heater temperature computation portion 379 computes temperatures that are a predetermined value higher than the heat generation temperature as the heat generation temperature of the socket heater 117 on the basis of the heat generation temperature of the hand heater 123 computed by the hand heater temperature computation portion 377.

The storage portion 40 is realized using a storage medium such as an IC memory, a hard disc, or an optical disc. In the storage portion 40, programs for operating the control device 30 so as to realize a variety of functions of the control device 30 or data that are used during the execution of the programs are stored in advance or temporarily stored each time a treatment is carried out. The control portion 37 and the storage portion 40 may be connected to each other not only using internal bus circuits in the device but also using communication lines such as local area network (LAN) or internet. In this case, the storage portion 40 may also be realized using a storage device that is different from the control device 30.

The storage portion 40 stores a main program 41, a heat balance characteristic table 43, the convection degree data 45, detected temperature data 47, and computed internal temperature data 49.

The control portion 37 reads and executes the main program 41, thereby controlling the operation of the inspection unit 10 regarding the inspection of the IC 22. The main program 41 includes a temperature control program 411 for causing the control portion 37 to function as the heat environment-setting portion 371 and the temperature control portion 373. The respective portions have been described to be realized in a software manner by causing the control portion 37 to read and execute the temperature control program 411, but can also be realized in a hardware manner by constituting electronic circuits that are exclusive for the respective portions.

The heat balance characteristic table 43 stores the values of the heat balance relative coefficients D₁, D₂, and D₃ that are specified in advance for each of a plurality of convection degrees in the accommodation space 15 which are defined by the combination of the driving state of the cooling device 70 and the driving state of the neutralization devices (refer to FIG. 6).

The convection degree data 45 stores the convection degrees in the accommodation space 15 which are set by the heat environment-setting portion 371.

The detected temperature data 47 includes first heat source temperature data 471, second heat source temperature data 472, and socket temperature data 473. The first heat source temperature data 471 stores the first heat source temperatures T_{H1} that are detected using the first temperature detector 125 in chronological order. The second heat source temperature data 472 stores the second heat source temperatures T_{H2} that are detected using the second temperature detector 118 in chronological order. The socket temperature data 473 stores the socket temperatures T_{SKT} that are detected using the third temperature detector 119 in chronological order.

The computed internal temperature data 49 stores the IC temperatures T_{IC} that are computed using the internal temperature computation portion 375 in chronological order.

### Flow of Treatments

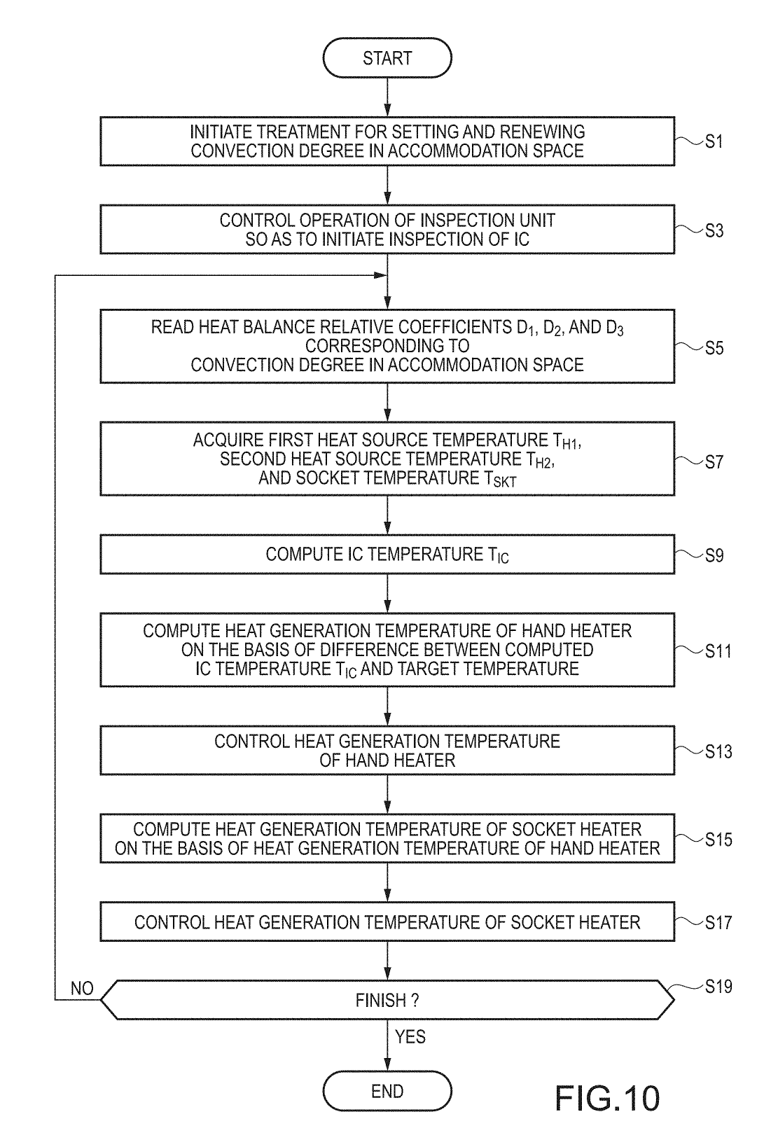

FIG. 10 is a flowchart showing a flow of treatments carried out by the control device 30. The treatments to be described herein can be realized by causing the control portion 37 to read and execute the main program 41 including the temperature control program 411 from the storage portion 40 and causing the respective portions in the IC test handler 1 to operate.

First, a treatment in which the heat environment-setting portion 371 acquires the actual driving state of the cooling device 70 and the actual driving state of the neutralization devices 13 as needed and sets the driving states as the convection degree in the accommodation space 15 is initiated (Step S1). Due to the above-described treatment, the convection degree data 45 are generated and renewed.

After that, the control portion 37 controls the operation of the inspection unit 10 and initiates the inspection of the IC 22 (Step S3). In addition, treatments of Step S5 to Step S17 are repeated each time the adsorption hand 120 adsorbs the IC package 20 accommodating a new IC 22 which is an inspection target and mounts the IC package on the mounting portion 110, whereby the hand heater 123 is caused to generate heat so that the IC temperatures T_{IC} which sequentially become inspection targets in inspection that is initiated in Step S3 reach the target temperature, and the heat generation temperature of the socket heater 117 is adjusted according to the heat generation temperature of the hand heater 123.

That is, first, in Step S5, the internal temperature computation portion 375 reads the values of the corresponding heat balance relative coefficients D₁, D₂, and D₃ according to the convection degree data 45 from the heat balance characteristic table 43. Subsequently, the internal temperature computation portion 375 acquires the detected temperature detected using the first temperature detector 125 as the first heat source temperatures T_{H1}, the detected temperature detected using the second temperature detector 118 as the second heat source temperatures T_{H2}, and the detected temperature detected using the third temperature detector 119 as the socket temperatures T_{SKT} (Step S7). In addition, the internal temperature computation portion 375 computes the IC temperature T_{IC} according to Expression (21) using the heat balance relative coefficients D₁, D₂, and D₃ read in Step S5, the first heat source temperature T_{H1}, the second heat source temperature T_{H2}, and the socket temperature T_{SKT} which have been acquired in Step S7 (Step S9).

Once the IC temperature T_{IC} is computed, the hand heater temperature computation portion 377 computes the heat generation temperature of the hand heater 123 on the basis of the difference between the IC temperature T_{IC} and the target temperature (Step S11). In addition, the temperature control portion 373 controls the hand heater 123 according to the heat generation temperature computed in Step S11 (Step S13).

In addition, the socket heater temperature computation portion 379 computes the heat generation temperature of the socket heater 117 by adding a predetermined value to the heat generation temperature of the hand heater 123 computed in Step S11 (Step S15). In addition, the temperature control portion 373 controls the socket heater 117 according to the heat generation temperature computed in Step S15 (Step S17).

After that, there is no more IC 22 (IC package 20) which is an inspection target, the process returns to Step S7, and the above-described treatments are repeated until the present treatment finishes (Step S19: NO).

As described above, according to the present embodiment, it is possible to compute the IC temperatures T_{IC} from the first heat source temperatures T_{H1} detected using the first temperature detector 125 as needed, the second heat source temperatures T_{H2} detected using the second temperature detector 118 as needed, and the socket temperatures T_{SKT} detected using the third temperature detector 119 as needed using the previously-set heat balance relative coefficients D₁, D₂, and D₃ as the heat balance characteristics of the respective temperatures. At this time, it is possible to variably set the heat balance relative coefficients D₁, D₂, and D₃ in consideration of the convection degree in the accommodation space 15. According to this, it is possible to accurately measure the temperature of the IC 22 and monitor the transition of the temperature.

In addition, it is possible to compute the heat generation temperature of the hand heater 123 on the basis of the difference between the computed IC temperature T_{IC} and the target temperature and control the heat generation temperature of the hand heater 123 so that the computed IC temperature T_{IC} reaches the target temperature. Here, even when the hand heater 123 generates heat at the same heat generation temperature, the actual temperatures of the IC 22 may not be even due to, for example, individual differences among the IC packages 20 such as surface roughness, the fluctuation of the heat environment in the chassis 11 such as the accommodation space 15, and the like. Additionally, there are cases in which the temperatures of the IC 22 are not even due to the deviation of the adsorption positions of the IC package 20 by the adsorption hand 120. However, according to the present embodiment, it is possible to control the hand heater 123 as needed while computing the IC temperatures T_{IC}. Therefore, it is possible to carry out inspection in a state in which the IC 22 is appropriately heated to the target temperature, and thus the reliability improves.

In addition, it is possible to adjust the heat generation temperature of the socket heater 117 on the basis of the heat generation temperature of the hand heater 123 to a temperature that is a predetermined value higher than the heat generation temperature of the hand heater at the same time as the heating of the IC package 20 (IC 22) using the hand heater 123. According to this, it is possible to heat the outside of the side surfaces of the IC package 20 and block the surrounding of the IC package 20 from heat. Therefore, it is possible to stably heat the IC 22 using the hand heater 123 by suppressing the influence of the heat environment in the accommodation space 15.

### MODIFICATION EXAMPLE 1

In the above-described embodiment, the inspection unit 10 including two heat sources that are the first heating portion 121 which is the first heat source and the second heating portion 115 which is the second heat source has been exemplified. However, a constitution in which an additional heating portion is separately installed at an appropriate place and thus n (n≥3) heat sources are provided may be employed. In this additional heating portion, a temperature detector for detecting the heat source temperature is provided. For example, as shown by the dot-and-dash line in FIG. 2, a heating portion 114 that heats the vicinity of the bottom portion of the socket 111 may be installed below the second heating portion 115.

In the case of Modification Example 1, as heat flow paths along which heat flows from the positions P_{Hn} (n=1, 2, . . . , n) of the n heat sources to the internal space position P_{OUT}, two heat flow paths that is a heat flow path which starts from the positions P_{Hn} of the respective heat sources respectively, joins together before the position in the IC P_{IC}, and reaches the internal space position P_{OUT} (a first heat flow path) and a heat flow path which starts from the positions P_{Hn} of the respective heat sources respectively, joins together before the socket position P_{SKT}, and reaches the internal space position P_{OUT} (a second heat flow path) will be considered.

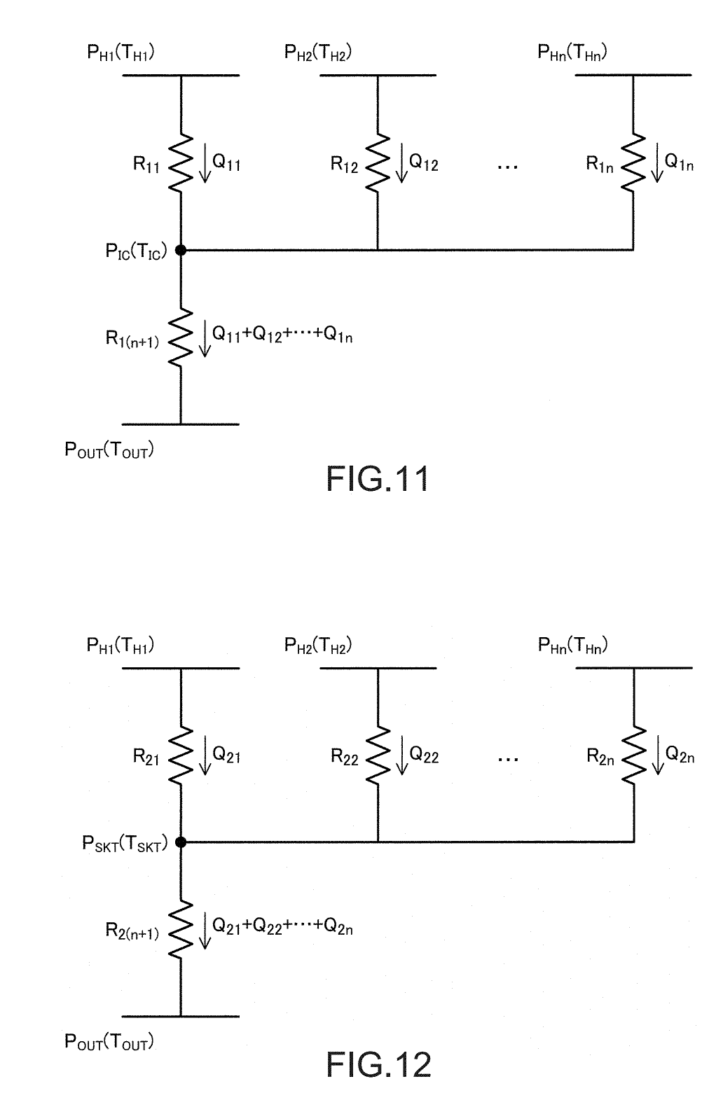

When an electrical circuit-like model of the first heat flow path is produced in consideration of the heat balance in the same manner as in the above-described embodiment, it is possible to build a heat flow path model as in FIG. 11. In addition, when an electrical circuit-like model of the second heat flow path is produced, it is possible to build a heat flow path model as in FIG. 12.

First, individual heat flows Q₁ₙ (n=1, 2, . . . , n) reaching the position in the IC P_{IC} from the positions P_{Hn} of the respective heat sources in the first heat flow path of FIG. 11 and a heat flow Q₁₁+Q₁₂+ . . . +Q₁ₙ in which the individual heat flows reach the internal space position P_{OUT} can be expressed by Expression (22) using heat source temperatures T_{Hn} (n=1, 2, . . . , n) of the respective heat sources, the IC temperature T_{IC}, and the internal space temperature T_{OUT}, and the respective heat resistances R₁₁ to R₁₍ₙ₊₁₎ shown in FIG. 11.

$${Q}_{11} = \frac{{T}_{H 1} - {T}_{IC}}{{R}_{11}} \\ {Q}_{12} = \frac{{T}_{H 2} - {T}_{IC}}{{R}_{12}} \\ ⋮ \\ {Q}_{1 n} = \frac{{T}_{Hn} - {T}_{IC}}{{R}_{1 n}} \\ {Q}_{11} + {Q}_{12} + … + {Q}_{1 n} = \frac{{T}_{IC} - {T}_{OUT}}{{R}_{1 ( n + 1 )}} \qquad ( 22 )$$

In addition, individual heat flows Q₂ₙ (n=1, 2, . . . , n) reaching the socket position P_{SKT} from the positions P_{Hn} of the respective heat sources in the second heat flow path of FIG. 12 and a heat flow Q₂₁+Q₂₂+ . . . +Q₂ₙ in which the individual heat flows reach the internal space position P_{OUT} can be expressed by Expression (23) using heat source temperatures T_{Hn} (n=1, 2, . . . , n) of the respective heat sources, the socket temperature T_{SKT}, and the internal space temperature T_{OUT}, and the respective heat resistances R₂₁ to R₂₍ₙ₊₁₎ shown in FIG. 12.

$${Q}_{21} = \frac{{T}_{H 1} - {T}_{SKT}}{{R}_{21}} \\ {Q}_{22} = \frac{{T}_{H 2} - {T}_{SKT}}{{R}_{22}} \\ ⋮ \\ {Q}_{2 n} = \frac{{T}_{Hn} - {T}_{SKT}}{{R}_{2 n}} \\ {Q}_{21} + {Q}_{22} + … + {Q}_{2 n} = \frac{{T}_{SKT} - {T}_{OUT}}{{R}_{2 ( n + 1 )}} \qquad ( 23 )$$

Expression (22) can be rearranged as Expression (24), and Expression (23) can be rearranged as Expression (25).

$$\begin{matrix}\frac{{T}_{H 1} - {T}_{IC}}{{R}_{11}} + \frac{{T}_{H 2} - {T}_{IC}}{{R}_{12}} + … + \frac{{T}_{Hn} - {T}_{IC}}{{R}_{1 n}} = \frac{{T}_{IC} - {T}_{OUT}}{{R}_{1 ( n + 1 )}} & ( 24 ) \\ \frac{{T}_{H 1} - {T}_{SKT}}{{R}_{21}} + \frac{{T}_{H 2} - {T}_{SKT}}{{R}_{22}} + … + \frac{{T}_{Hn} - {T}_{SKT}}{{R}_{2 n}} = \frac{{T}_{SKT} - {T}_{OUT}}{{R}_{2 ( n + 1 )}} & ( 25 )\end{matrix}$$

Next, in order to remove the element of the internal space temperature T_{OUT}, Expression (24) is rearranged for the internal space temperature T_{OUT}, thereby obtaining Expression (26), and Expression (23) is rearranged for the internal space temperature T_{OUT}, thereby obtaining Expression (27).

$$\begin{matrix}{R}_{1 ( n + 1 )} ( \frac{{T}_{H 1} - {T}_{IC}}{{R}_{11}} + \frac{{T}_{H 2} - {T}_{IC}}{{R}_{12}} + … \frac{{T}_{Hn} - {T}_{IC}}{{R}_{1 n}} - \frac{{T}_{IC}}{{R}_{1 ( n + 1 )}} ) = - {T}_{OUT} & ( 26 ) \\ {R}_{2 ( n + 1 )} ( \frac{{T}_{H 1} - {T}_{SKT}}{{R}_{21}} + \frac{{T}_{H 2} - {T}_{SKT}}{{R}_{22}} + … \frac{{T}_{Hn} - {T}_{SKT}}{{R}_{2 n}} - \frac{{T}_{SKT}}{{R}_{2 ( n + 1 )}} ) = - {T}_{OUT} & ( 27 )\end{matrix}$$

Expression (26) and Expression (27) can be rearranged as Expression (28).

$$\frac{{R}_{1 ( n + 1 )}}{{R}_{11}} ( {T}_{H 1} - {T}_{IC} ) + \frac{{R}_{1 ( n + 1 )}}{{R}_{12}} ( {T}_{H 2} - {T}_{IC} ) + … + \frac{{R}_{1 ( n + 1 )}}{{R}_{1 n}} ( {T}_{Hn} - {T}_{IC} ) - {T}_{IC} = \frac{{R}_{2 ( n + 1 )}}{{R}_{21}} ( {T}_{H 1} - {T}_{SKT} ) + \frac{{R}_{2 ( n + 1 )}}{{R}_{22}} ( {T}_{H 2} - {T}_{SKT} ) + … + \frac{{R}_{2 ( n + 1 )}}{{R}_{2 n}} ( {T}_{Hn} - {T}_{SKT} ) - {T}_{SKT} \qquad ( 28 )$$

Here, the coefficients of the respective elements of the left side of Expression (28) can be rearranged as Expressions (29), and the coefficients of the respective elements of the right side of Expression (28) can be rearranged as Expressions (30).

$$\begin{matrix}\frac{{R}_{1 ( n + 1 )}}{{R}_{11}} = {a}_{1} , \frac{{R}_{1 ( n + 1 )}}{{R}_{12}} = {a}_{2} , … , \frac{{R}_{1 ( n + 1 )}}{{R}_{1 n}} = {a}_{n} & ( 29 ) \\ \frac{{R}_{2 ( n + 1 )}}{{R}_{21}} = {b}_{1} , \frac{{R}_{2 ( n + 1 )}}{{R}_{22}} = {b}_{2} , … , \frac{{R}_{2 ( n + 1 )}}{{R}_{2 n}} = {b}_{n} & ( 30 )\end{matrix}$$

At this time, Expression (28) can be rearranged as Expression (31).

$${a}_{1} ( {T}_{H 1} = {T}_{IC} ) + {a}_{2} ( {T}_{H 2} - {T}_{IC} ) + … + {a}_{n} ( {T}_{H 2} - {T}_{IC} ) - {T}_{IC} = {b}_{1} ( {T}_{H 1} - {T}_{SKT} ) + {b}_{2} ( {T}_{H 2} - {T}_{SKT} ) + … + {b}_{a} ( {T}_{H 2} - {T}_{SKT} ) - {T}_{SKT} \qquad ( 31 )$$

When Expression (31) is rearranged for the IC temperature T_{IC}, Expression (32) is obtained.

$${T}_{IC} = \frac{\begin{matrix}( {a}_{1} - {b}_{1} ) {T}_{H 1} + ( {a}_{2} - {b}_{2} ) {T}_{H 2} + … + \\ ( {a}_{n} - {b}_{n} ) {T}_{Hn} + ( {b}_{1} + {b}_{2} + … + {b}_{n} + 1 ) {T}_{SKT}\end{matrix}}{( {a}_{1} + {a}_{2} + … + {a}_{n} + 1 )} \qquad ( 32 )$$

Heat balance relative coefficients D₁ to Dₙ₊₁ represented by Expressions (33) are introduced using the respective coefficients aₙ (n=1, 2, . . . , n), bn (n=1, 2, . . . , n) defined by Expressions (29) and (30).

$$\frac{{a}_{1} - {b}_{1}}{{a}_{1} + {a}_{2} + … + {a}_{n} + 1} = {D}_{1} \\ \frac{{a}_{2} - {b}_{2}}{{a}_{1} + {a}_{2} + … + {a}_{n} + 1} = {D}_{2} \\ ⋮ \\ \frac{{a}_{n} - {b}_{n}}{{a}_{1} + {a}_{2} + … + {a}_{n} + 1} = {D}_{n} \\ \frac{{b}_{1} + {b}_{2} + … + {b}_{n} + 1}{{a}_{1} + {a}_{2} + … + {a}_{n} + 1} = {D}_{n + 1} \qquad ( 33 )$$

Expression (32) can be rearranged as Expression (34) using the heat balance relative coefficients D₁ to Dₙ₊₁.

T_{IC}=D₁T_{H1}+D₁T_{H2}+ . . . +DₙT_{Hn}+Dₙ₊₁T_{SKT} (34)

In Expression (34), the heat source temperatures T_{Hn} of the respective heat sources and the socket temperature T_{SKT} can be detected using the corresponding temperature detectors, and thus all of the temperatures are known. Therefore, when the values of the heat balance relative coefficients D₁ to Dₙ₊₁ are specified in advance, it is possible to compute the IC temperature T_{IC}. In the present modification example as well, the convection degree is defined by the combination of the driving state of the cooling device 70 and the driving state of the neutralization devices 13, and a heat balance characteristic table storing the values of the heat balance relative coefficients D₁ to Dₙ₊₁ for each of the convection degrees is prepared in advance. In addition, the IC temperatures T_{IC} is computed according to Expression (34) by reading and using the values of the heat balance relative coefficients D₁ to Dₙ₊₁ corresponding to the actual convection degree in the accommodation space 15.

### OTHER MODIFICATION EXAMPLES

For example, the method for heating the IC package 20 is not limited to the method in which the IC package 20 is heated by being brought into contact with the first heating portion 121 including the hand heater 123 and may be a method in which the IC package 20 is put into a chamber (constant-temperature tank) having an inside controlled to a predetermined temperature and is heated to the target temperature.

In the above-described embodiment, the convection degree in the accommodation space 15 is defined by the combination of the driving state of the cooling device 70 and the driving state of the neutralization devices 13, and the heat balance characteristic table storing the values of the heat balance relative coefficients D₁, D₂, and D₃ for each of the convection degrees is prepared in advance. In addition, the IC temperatures T_{IC} is computed using the heat balance relative coefficients D₁, D₂, and D₃ matching the actual driving state of the cooling device 70 and the actual driving state of the neutralization devices 13. However, the convection degree may be specified by installing a wind speed meter in the accommodation space 15 and detecting the wind speed in the accommodation space 15. In addition, the heat balance relative coefficients D₁, D₂, and D₃ of the convection degree corresponding to the specified convection degrees may be used. In this case, a heat balance characteristic table setting the heat balance relative coefficients D₁, D₂, and D₃ corresponding to each of the wind speeds may be prepared in advance. The present modification example can also be applied to Modification Example 1.

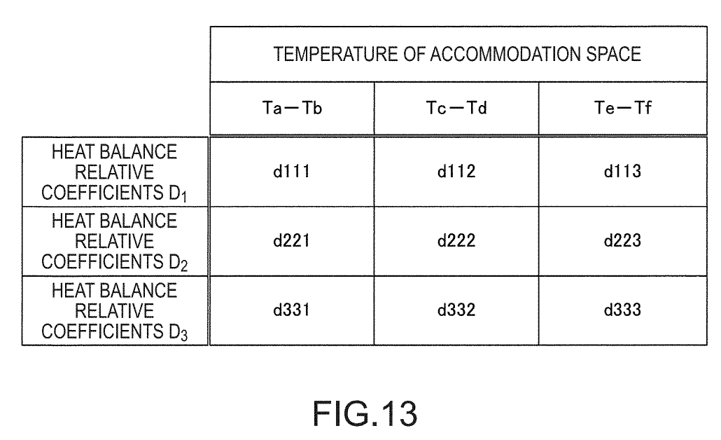

In addition, a constitution in which the heat balance relative coefficients D₁, D₂, and D₃ are variably set using the temperature in the chassis 11 in addition to the convection degree may also be employed. In this case, a heat balance characteristic table storing the values of the heat balance relative coefficients D₁, D₂, and D₃ corresponding to each of the temperatures of the accommodation space 15 may be prepared in advance. In addition, the temperature of the accommodation space 15 detected using the thermometer 80 is acquired as needed, and the corresponding heat balance relative coefficients D₁, D₂, and D₃ are used to compute the IC temperatures T_{IC}. According to this, it is possible to consider the temperature of the accommodation space 15 as the heat environment and variably set the heat balance relative coefficients D₁, D₂, and D₃, and thus the IC temperatures T_{IC} can be accurately measured. FIG. 13 is a view showing a data constitution example of the heat balance characteristic table in the present modification example. As shown in FIG. 13, in the heat balance characteristic table of the present modification example, the values of the heat balance relative coefficients D₁, D₂, and D₃ are set depending on the stepwise temperature ranges. The present modification example can also be applied to Modification Example 1.

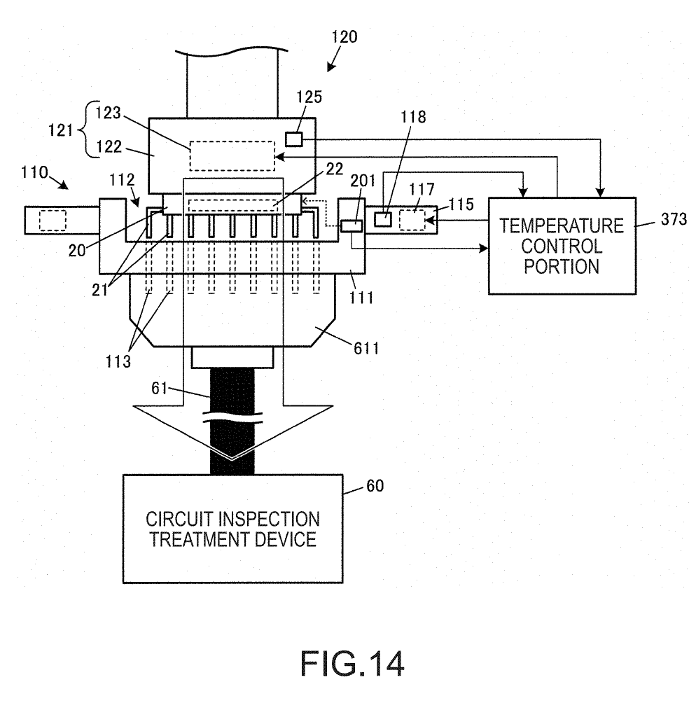

In the above-described embodiment, the heat flows moving through the socket position P_{SKT} are used as the examples of the heat flow Q₂₁, the heat flow Q₂₂, or the heat flow Q₂ₙ (n=1, 2, . . . , n) moving along the second heat flow path, and the description is made using the socket temperature T_{SKT}. However, as shown in FIG. 14, a surface temperature T_{PKG} of the IC package 20 may be used instead of the socket temperature T_{SKT}. In this case, the surface temperature T_{PKG} of the IC package 20 may be detected using a non-contact thermometer 201 such as an infrared radiation thermometer installed at an appropriate place. The installation position of the non-contact thermometer 201 is not particularly limited, and the non-contact thermometer can be installed in, for example, the socket 111 or the like on which the IC package 20 is mounted. In FIG. 14, the position of the non-contact thermometer 201 is determined so that a side surface of the IC package 20 becomes a measurement target position when the IC package 20 is mounted on the socket 111.

In the above-described embodiment, the detected temperatures detected using the second temperature detector 118 are used as a reference socket temperature T_{SKT0} and the socket temperature T_{SKT}. However, the surface temperature or the bottom surface temperature of the socket 111 may be measured using the contact thermometer such as an infrared radiation thermometer and be used as the reference socket temperature T_{SKT0} and the socket temperature T_{SKT}.

In the above-described embodiment, the temperature of the first heating portion 121 is detected using the first temperature detector 125 and used as the first heat source temperatures T_{H1}, the temperature of the second heating portion 115 is detected using the second temperature detector 118 and used as the second heat source temperatures T_{H2}, and the IC temperatures T_{IC} is computed. However, a constitution in which the heat generation temperature of the hand heater 123 computed by the hand heater temperature computation portion 377 is used as the first heat source temperatures T_{H1}, the heat generation temperature of the socket heater 117 computed by the socket heater temperature computation portion 379 is used as the second heat source temperatures T_{H2}, and the IC temperatures T_{IC} are computed may be employed. The present modification example can also be applied to Modification Example 1.

In the above-described embodiment, the IC has been exemplified as the electronic circuit which is the measurement subject, and the IC test handler for inspecting the IC has been described, but the embodiment can also be applied to inspection apparatuses that inspect the electrical characteristics of electronic components (electronic devices), electronic component modules, and the like in the same manner.

In the above-described embodiment, the control device 30 has been described as a separate device from the circuit inspection treatment device 60, but the control device may be constituted of a single device having both functions.

In the above-described embodiment, the control in which the heat generation temperature of the socket heater 117 is set to a temperature that is a predetermined value higher than the heat generation temperature of the hand heater 123 has been exemplified, but a constitution in which the heat generation temperature of the socket heater 117 is fixed to a predetermined value (for example, 180° C.) and the heat generation temperature of the hand heater 123 is controlled to a temperature that is equal to or lower than the heat generation temperature of the socket heater 117 may be employed. In addition, the heat generation temperature of the hand heater 123 and the heat generation temperature of the socket heater 117 may be controlled to the same temperature.

The entire disclosure of Japanese Patent Application No. 2016-221168 filed on Nov. 14, 2016 is expressly incorporated by reference herein.

What is claimed is:

1. A temperature-measuring apparatus comprising:
a first heat source capable of changing a heat generation temperature;
a mounting portion on which a measurement subject accommodating a measurement target is mounted;
a second heat source which is a heat source that heats the mounting portion and is capable of changing a heat generation temperature;
a temperature sensor that detects a temperature of a predetermined position other than the measurement target on a heat flow path which comes from the first heat source and passes through the measurement subject; and
a temperature computation portion that computes a temperature of the measurement target on the basis of heat balance characteristics of the temperature of the measurement target, a temperature of the first heat source, a temperature of the second heat source, and the temperature of the predetermined position, the temperatures of the first heat source, the temperature of the second heat source, and the detected temperature of the predetermined position.

2. The temperature-measuring apparatus according to claim 1,
wherein the heat generation temperature of the second heat source is set to be higher than the heat generation temperature of the first heat source.

3. The temperature-measuring apparatus according to claim 1,
wherein the temperature sensor detects a temperature of the mounting portion as the temperature of the predetermined position.

4. The temperature-measuring apparatus according to claim 1, further comprising:
a conveyance portion that holds and conveys the measurement subject to the mounting portion and halts at a predetermined halt position during measurement,
wherein the first heat source is provided in the conveyance portion.

5. The temperature-measuring apparatus according to claim 1, further comprising:
a control portion that controls the temperatures of the heat sources on the basis of the computed temperature of the measurement target.

6. The temperature-measuring apparatus according to claim 1,
wherein the temperature computation portion variably sets the heat balance characteristics depending on heat environments.

7. The temperature-measuring apparatus according to claim 6,
wherein the temperature computation portion variably sets the heat balance characteristics depending on the heat environments on the basis of any one of a temperature in an apparatus chassis and a convection degree.

8. An inspection apparatus comprising:
the temperature-measuring apparatus according to claim 1, in which the measurement target is an electronic circuit.

9. An inspection apparatus comprising:
the temperature-measuring apparatus according to claim 2, in which the measurement target is an electronic circuit.

10. The inspection apparatus according to claim 8,
wherein the mounting portion has a socket for the electronic circuit,
a circuit inspection treatment device which is installed in a predetermined space in the apparatus chassis, has an operation compensation temperature that is lower than the temperatures of the heat sources, and is connected to the socket with an electrical wire and a cooling device for cooling the circuit inspection treatment device are provided, and
the temperature computation portion variably sets the heat balance characteristics depending on a heat environment of the predetermined space.

11. The inspection apparatus according to claim 8,
wherein the temperature sensor detects a temperature of a position close to the electrical wire in the socket as the temperature of the predetermined position.

12. A control method of a temperature-measuring apparatus including a first heat source capable of changing a heat generation temperature, a mounting portion on which a measurement subject accommodating a measurement target is mounted, a second heat source which is a heat source that heats the mounting portion and is capable of changing a heat generation temperature, and a temperature sensor that detects a temperature of a predetermined position other than the measurement target on a heat flow path which comes from the first heat source and passes through the measurement subject, the control method comprising:
computing a temperature of the measurement target on the basis of heat balance characteristics of the temperature of the measurement target, a temperature of the first heat source, a temperature of the second heat source, and the temperature of the predetermined position, the temperature of the first heat source, the temperature of the second heat source, and the detected temperature of the predetermined position.
